(19) United States
(12) Patent Application Publication
(10) Pub. No.: US 2017/0309767 A1
(43) Pub. Date: Oct. 26, 2017

(54) INCREMENTAL SOLAR ANTENNA ARRAY FABRICATION

(71) Applicant: NovaSolix, Inc., Palo Alto, CA (US)

(72) Inventors: Laurence H. COOKE, Los Gatos, CA (US); Andreas HEGEDUS, Burlingame, CA (US); Jyotsna IYER, Saratoga, CA (US); Paul COMITA, Menlo Park, CA (US); William J. ALLEN, Cupertino, CA (US)

(21) Appl. No.: 15/249,953

(22) Filed: Aug. 29, 2016

Related U.S. Application Data
(63) Continuation-in-part of application No. 15/133,807, filed on Apr. 20, 2016.

(51) Int. Cl. H01L 31/054; H01L 31/18; H01L 31/02

(52) U.S. Cl. CPC H01L 31/0543; H01L 31/0201; H01L 31/18

(57) ABSTRACT

A solar antenna array may comprise an array of carbon nanotube antennas that may capture and convert sunlight into electrical power. A method for constructing the solar antenna array from a glass top down to an aluminum covered plastic bottom such that light passing through the glass top and/or reflected off the aluminum bottom both may be captured by the antennas sandwiched between. Techniques for patterning the glass to further direct the light toward the antennas and techniques for continuous flow fabrication and testing are also described.

### CROSS-REFERENCE TO RELATED APPLICATION

This application is a continuation-in-part of U.S. patent application Ser. No. 15/133,807, filed on Apr. 20, 2016, and incorporated herein by reference.

### FIELD OF ENDEAVOR

Various aspects of this disclosure may pertain to an incremental economical series of manufacturing processes of visible light rectenna arrays for the conversion of solar energy to electricity.

### BACKGROUND

Rectifiers for AC to DC conversion of high frequency signals have been well known for decades. A particular type of diode rectifier when coupled to an antenna, called a Rectenna, has also been known for decades. More specifically, over 20 years ago, Logan described using an array of Rectennas to capture and convert microwaves into electrical energy in U.S. Pat. No. 5,043,739 granted Aug. 27, 1991. However, the dimensions of the antenna limited the frequency until recently, when Gritz, in U.S. Pat. No. 7,679,957 granted Mar. 16, 2010, described using a similar structure for converting infrared light into electricity, and Pietro Siciliano suggested that such a structure may be used for sunlight in “Nano-Rectenna For High Efficiency Direct Conversion of Sunlight to Electricity: by Pietro Siciliano of The Institute for Microelectronics and Microsystems IMM-CNR, Lecce (Italy).

Still, the minimum dimensions required for such visible light rectennas are generally in the tens of nanometers. While these dimensions may be accomplished by today's deep submicron masking technology, such processing is typically far more expensive than the current solar cell processes, which require much larger dimensions.

Still, as Logan pointed out in U.S. Pat. No. 5,043,739, the efficiency of microwave Rectennas can be as high as 40%, more than double that of typical single junction poly-silicon solar cell arrays, and when using metal-oxide-metal (MOM) rectifying diodes, as Pietro suggests, no semiconductor transistors are needed in the array core.

As such, it may be advantageous to be able to utilize the existing fine geometry processing capability of current semiconductor fabrication without incurring the cost of such manufacturing.

Also, recently, Rice University reported that their researchers created a carbon nanotube (CNT) thread with metallic-like electrical and thermal properties. Furthermore, carbon nanotube structures are becoming more manufacturable, as described by Rosenberger et al. in U.S. Pat. No. 7,354,977 granted Apr. 8, 2008. Various forms of continuous CNT growth may have also been contemplated, such as Lemaire et. al. repeatedly harvesting a CNT “forest’ while it is growing in U.S. Pat. No. 7,744,793 granted Jun. 29, 2010, and/or put into practice using techniques described by Predtechensky et al. in U.S. Pat. No. 8,137,653 granted Mar. 20, 2012. Grigorian et al. describes continuously pushing a carbon gas through a catalyst backed porous membrane to grow CNTs in U.S. Pat. No. 7,431,985 granted Oct. 7, 2008.

Furthermore, others have contemplated using CNTs for various structures such as Rice University's CNT thread as described in “Rice's carbon nanotube fibers outperform copper,” by Mike Williams, posted on Feb. 13, 2014 at: news.rice.edu/2014/02/13/rices-carbon-nanotube-fibers-outperform-copper-2; magnetic data storage as described by Tyson Winarski in U.S. Pat. No. 7,687,160 granted Mar. 30, 2010; and in particular, antenna-based solar cells, as described by Tadashi Ito et al. in US Patent Publication 2010/0244656 published Sep. 30, 2010. Still, Ito et al. did not describe methods to inexpensively construct carbon nanotube solar antennas for efficient conversion of solar energy.

### SUMMARY OF VARIOUS EMBODIMENTS

Various embodiments of the invention may relate to ways to manufacture structures of CNT rectenna arrays for converting sunlight into electricity, which may utilize stamps made using current IC masking techniques and self-aligning process steps and to achieve the dimensions required for the antennas.

The structure of the rectenna array may include an array of CNT antennas connecting a ground plane to a negative voltage plane through metal insulator insulator carbon (MIIC) diodes. The antennas may be of varying lengths and orientations, distributed for maximum reception of the full spectrum of ambient sunlight either from ¼ wavelengths or harmonic multiples of ¼ wavelengths. The small diameter CNTs connecting to the larger voltage plane may also form geometric diodes. Single ¼-wavelength antenna diode combinations may half-wave rectify the received light. Two coupled ¼-wavelength antenna diode combinations may full-wave rectify the received light.

The manufacture of these arrays may be incrementally modified to transfer from a low volume semiconductor related process to a high volume glass and plastic based continuous flow process.

In one embodiment, the rectenna arrays may be constructed by a series of depositions from a glass base up to a plastic back such that the antennas collect light through the glass base. Aluminum bus bars may further reflect the received or retransmitted light to be re-collected by the antennas.

In another embodiment, stamps may be constructed to pattern metals for selectively etching the structures necessary to create the CNT antenna array. Alternatively, the stamps may be used to directly pattern metal, and may be further used to pattern drums for high volume continuous CNT antenna array manufacturing.

In yet another embodiment, a shadow mask may be used to selectively etch a deposited oxide. Furthermore, a clear plastic sheet may separate metal bus bars from the CNT antennas. A laser may be used to form vias in the plastic sheet. The plastic sheet may be a polycarbonate sheet. A cover layer of plastic may be deposited on the bus bars, thereby forming a continuous roll of flexible solar cells.

### BRIEF DESCRIPTION OF THE DRAWINGS

Various embodiments of the invention will now be described in connection with the attached drawings, in which:

FIG. 1 is an electrical diagram of a combined diode and antenna according to an embodiment of the invention,

FIG. 2 is another electrical diagram of a pair of diodes and antennas according to an embodiment of the invention,

FIG. 3 is a logical diagram of an array of antennas and diodes according to an embodiment of the invention,

FIGS. 4 and 5 are diagrams of cross-sections of an antenna array depicting a single Diode and Carbon Nanotube Antenna according to embodiments of the invention,

FIG. 6 is a diagram of top view of a section of an array of antennas according to an embodiment of the invention,

FIGS. 7 through 15 are cross sections of an antenna array during successive steps of manufacture according to an embodiment of the invention,

FIG. 16 is a top view of the vias and bus bars during steps of their construction, according to an embodiment of the invention,

FIGS. 17 and 18 are cross-sections of an antenna array during the final steps of manufacturing according to an embodiment of the invention, and

FIG. 19 is a diagram of continuous flow process steps according to an embodiment of the invention.

### DESCRIPTION OF VARIOUS EMBODIMENTS

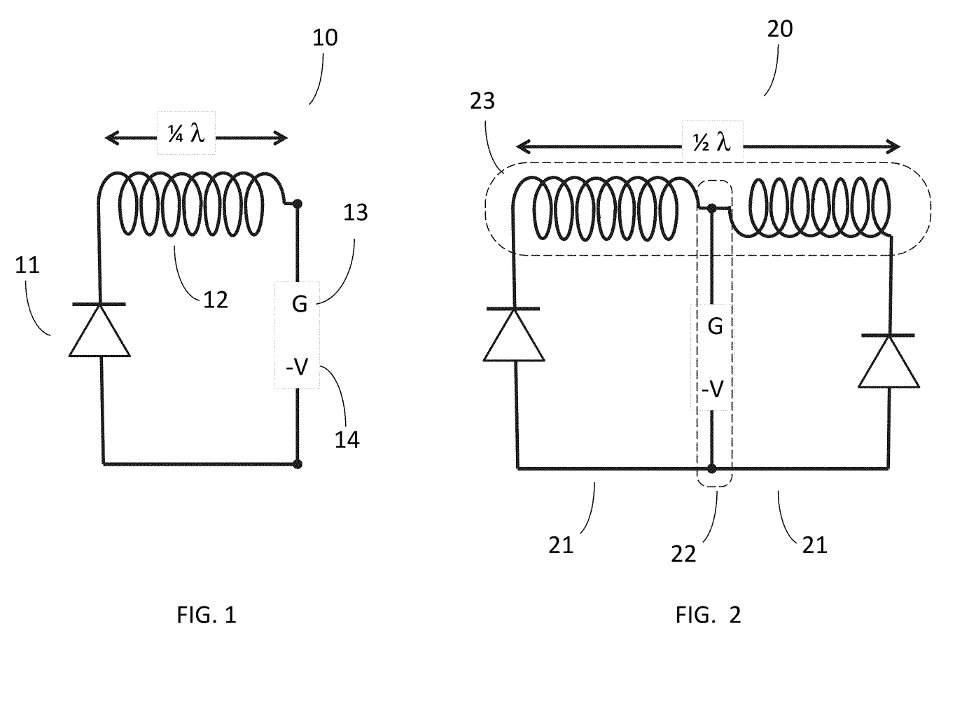

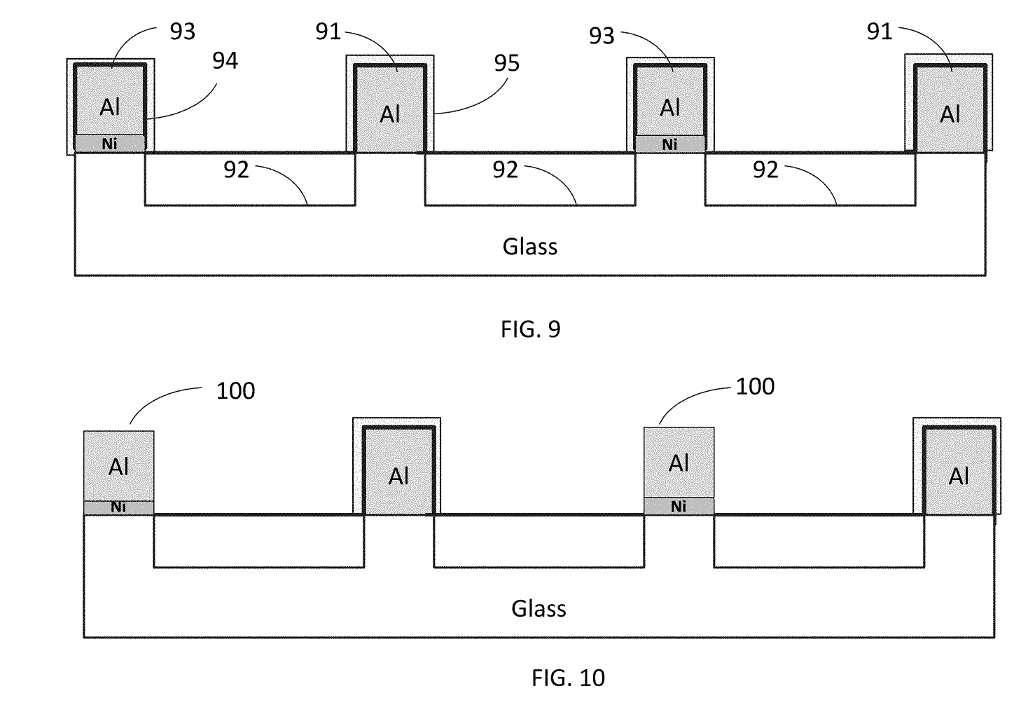

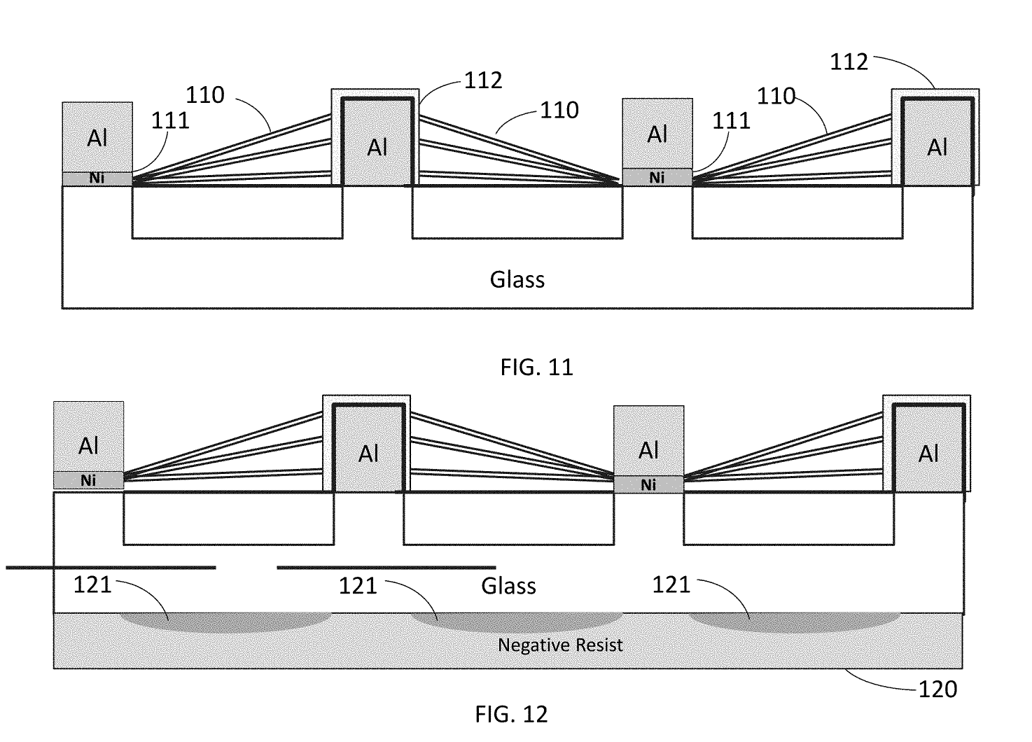

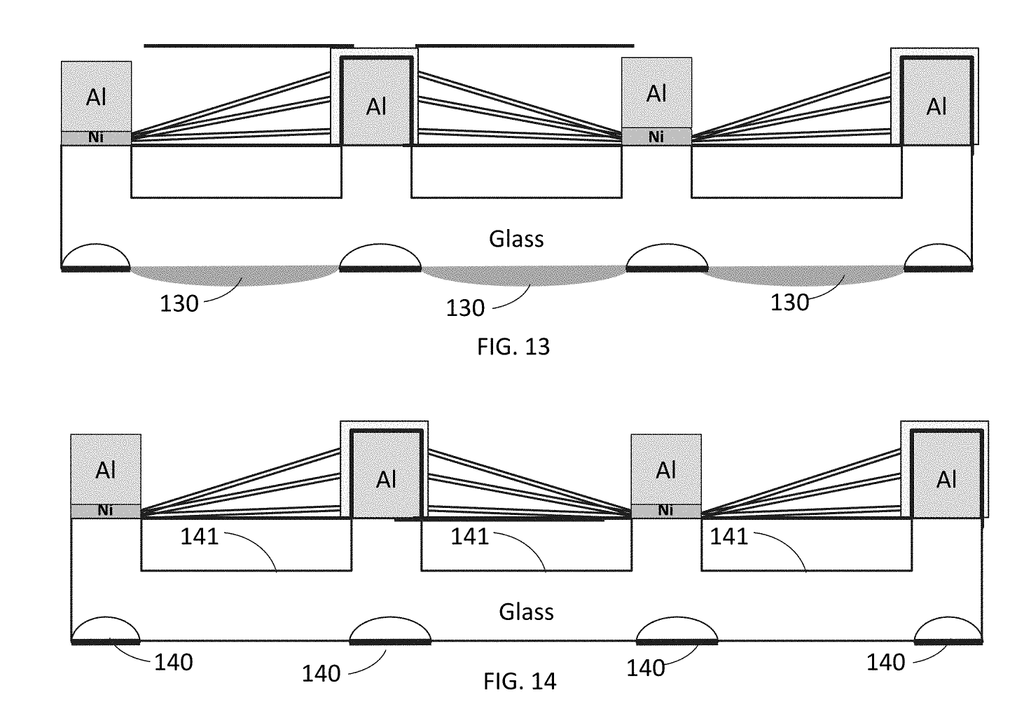

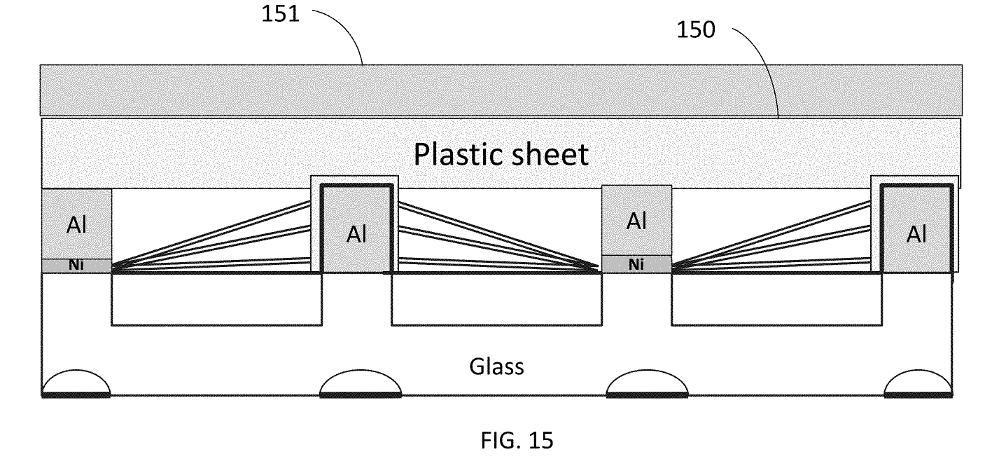

Embodiments of the present invention are now described with reference to FIGS. 1-19, it being appreciated that the figures may illustrate the subject matter of various embodiments and may not be to scale or to measure.

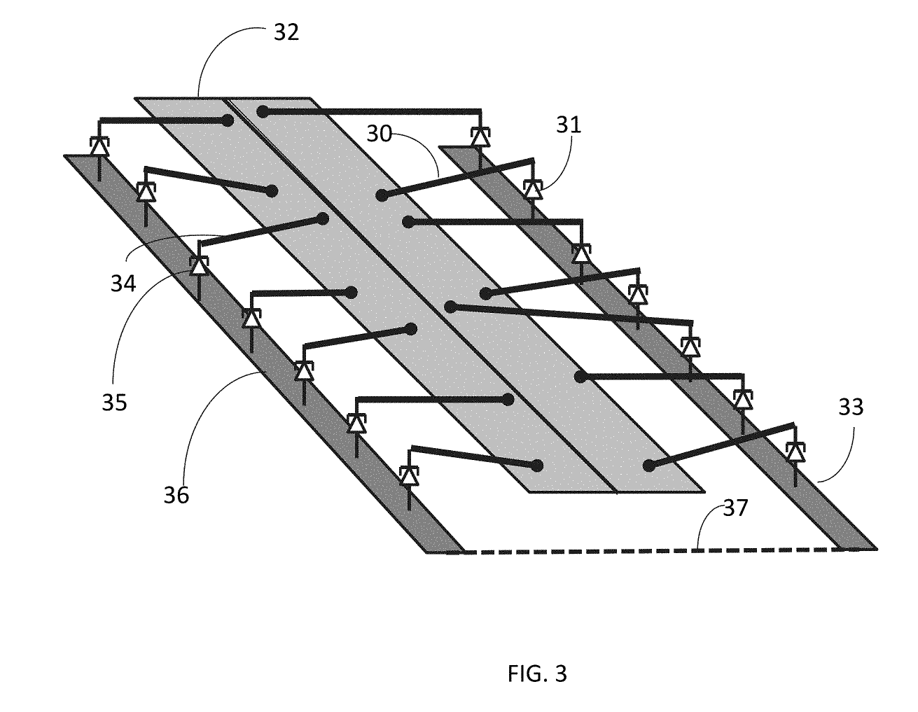

An electrical diagram 10 of a combined diode and antenna according to an embodiment of the invention is shown in FIG. 1. A diode 11 and a ¼-wavelength antenna 12 may be coupled together, with the antenna 12 further connected to a ground line 13 and the diode 11 connected to a—Voltage line 14, to form a ½-wave rectified structure. Another electrical diagram 20 of a pair of diodes and antennas according to another embodiment of the invention, is shown in FIG. 2. Two structures 21, each equivalent to the electrical diagram shown in FIG. 1, may be coupled to common Ground and—Voltage lines 22, to form a full-wave rectified structure.

Reference is now made to FIG. 3, a conceptual diagram of an array of antennas and diodes according to an embodiment of the invention. The antenna 30 and diode 31 may be respectively connected to the ground plane 32 and the power plane 33 in a manner similar to the electrical diagram in FIG. 1. A second antenna 34 and diode 35 may be respectively connected to another side of the ground plane 32 and another power plane 36, which may in turn be connected 37 to the original power plane. Together, the antennas 30,34 and diodes 31,35 may be connected to the power 33,36 and ground 32 planes in a manner similar to the electrical diagram in FIG. 2. The antennas may be of varying lengths and may be randomly placed between the diodes and the ground plane 32. The antennas may be metallic carbon nanotubes.

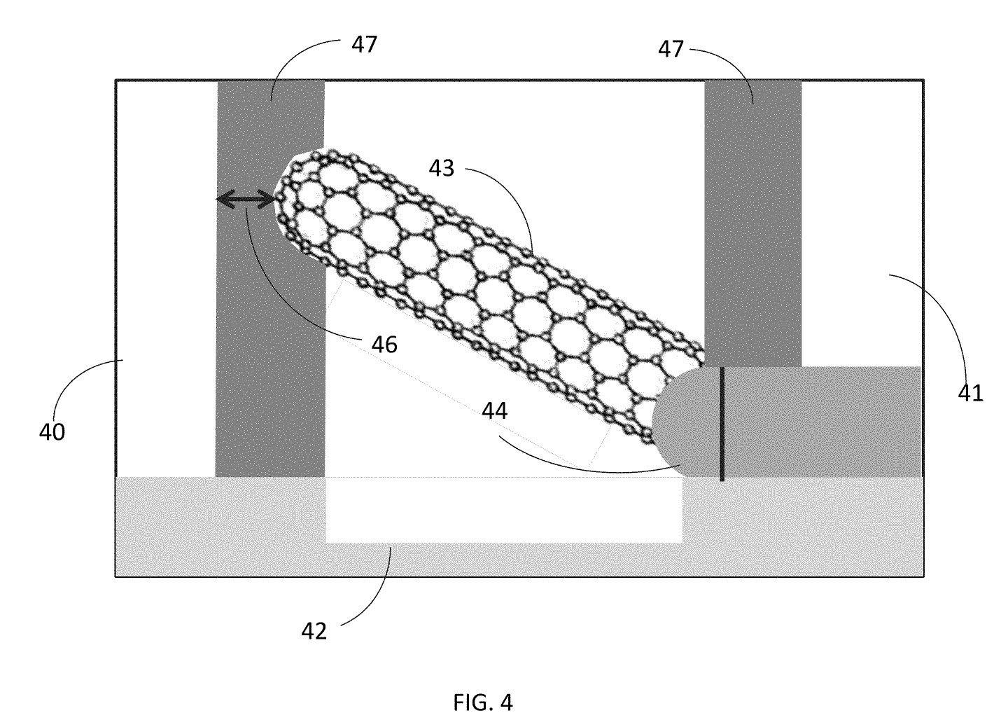

Reference is now made to FIG. 4, a diagram of a cross-section of an antenna array, depicting a single diode and CNT antenna according to an embodiment of the invention. The antenna 43 may be either a single-walled metallic carbon nanotube, or a multi-walled carbon nanotube, which may be attached to the ground plane 41 via a catalyst 44. The catalyst may be used to grow the CNT. The catalyst maybe composed of nickel, iron, cobalt, or some other suitable metal or alloy of metals. The tip of the carbon nanotube 43, coupled to oxide layer 47, may form a metal-oxide-carbon (MOC) diode 46 connected to the voltage plane 40. The power and ground planes may be insulated from each other via a base 42. The base 42 may be, for example, a ceramic, glass or a plastic material. The power 40 and ground 41 planes may be composed of one or more metals.

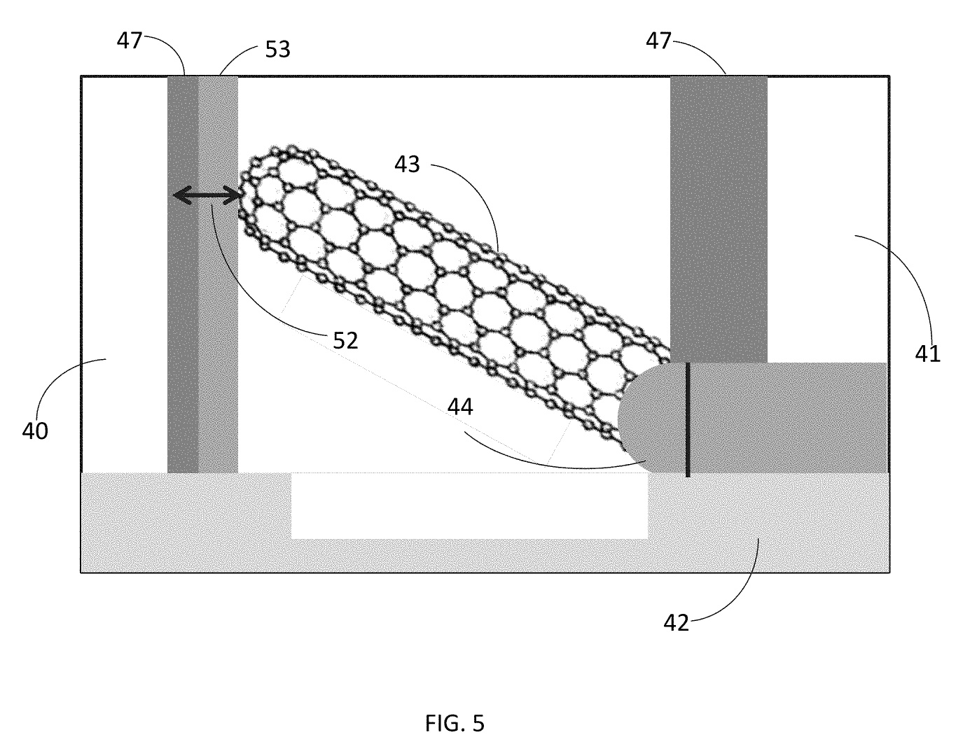

Reference is now made to FIG. 5, another diagram of the cross section of an antenna array depicting a single Diode and CNT Antenna according to another embodiment of the invention. In this case a different oxide layer 53 may cover the original oxide layer 47 to form a metal-insulator-insulator-carbon (MIIC) diode 52 between the CNT 43 and the power plane 40.

In order to efficiently rectify visible light, the diodes may need to have a cutoff frequency above 700 Thz. This may require diodes (46 or 52) with sufficiently small capacitance, which may be accomplished by growing CNTs under 15 nanometers in diameter to oxides that are each a few nanometers thick. In addition to a MOC or MIIC diode, the small diameter of the CNT connecting to the large flat side of the power plane may form a geometric diode. Furthermore, the antennas lengths and directions may vary to cover the entire spectrum of un-polarized sun light. This may be accomplished by varying the distance the CNTs 43 must cover from the ground 41 plane to the power plane 40, such that the difference of the shortest to the longest CNT is greater than the difference between a ¼ wavelength of ultraviolet light (˜80 nanometers) and ¼ wavelength of infrared light (˜640 nanometers). This may ensure that at least one harmonic of all frequencies of light may be covered by the range of CNT lengths.

Such small structures may require the combination of complex semiconductor processing coordinated with controlled growth of carbon nanotube antennas. It may, therefore, be desirable to leverage as much of existing semiconductor processing as possible, and to incrementally modify the process to reduce cost and increase volume. As such, an initial manufacturing process may rely on existing semiconductor mask and etching operations, and may gradually change to a continuous flow of maskless operations.

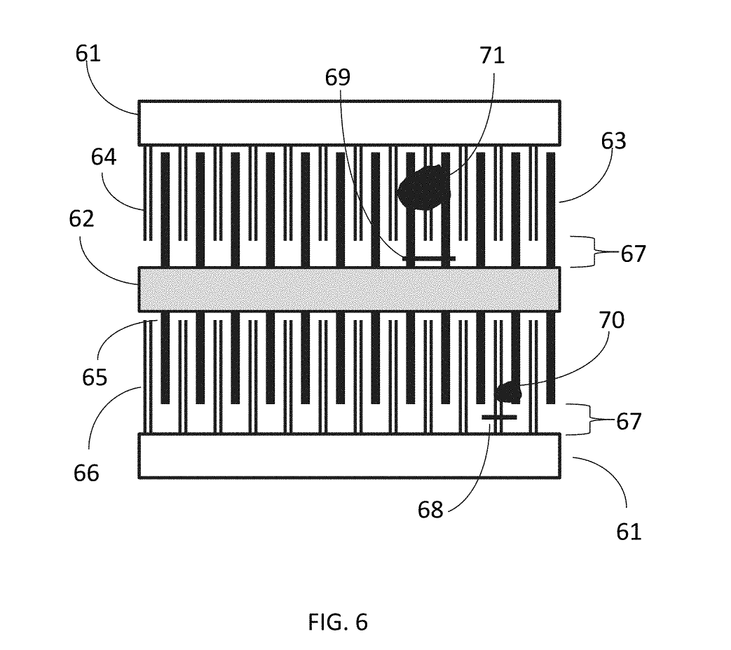

Reference is now made to FIG. 6, a diagram of a top view of a section of an array of antennas according to an embodiment of the invention. This structure may include large power 61 and ground 62 bus lines, with interleaved smaller power 64 and ground 63 fingers, with the CNT antennas spanning between adjacent power 66 and ground 67 fingers. For the CNTs grown between the fingers to vary up to a ½ micron, the space between the fingers may be at least a micron, and to maximize the CNT light absorption area, the fingers may be as narrow as may be economically manufactured.

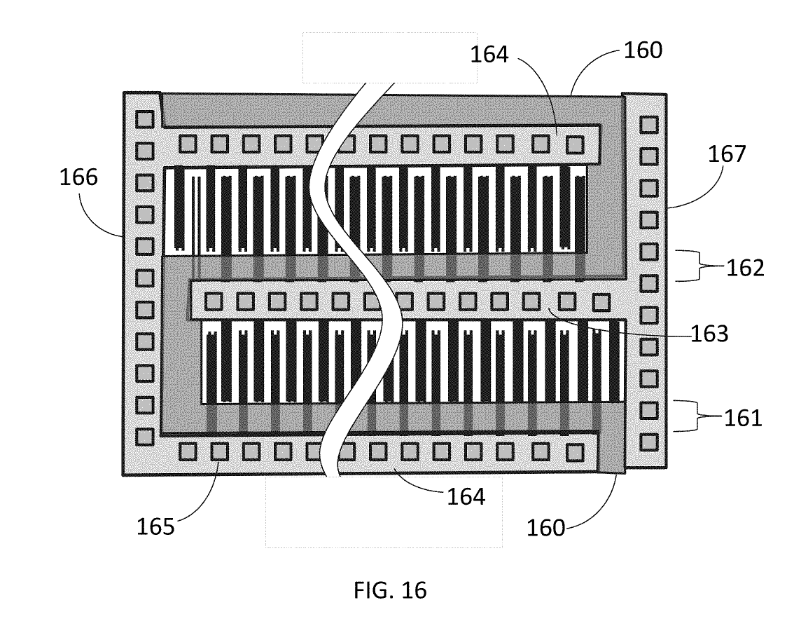

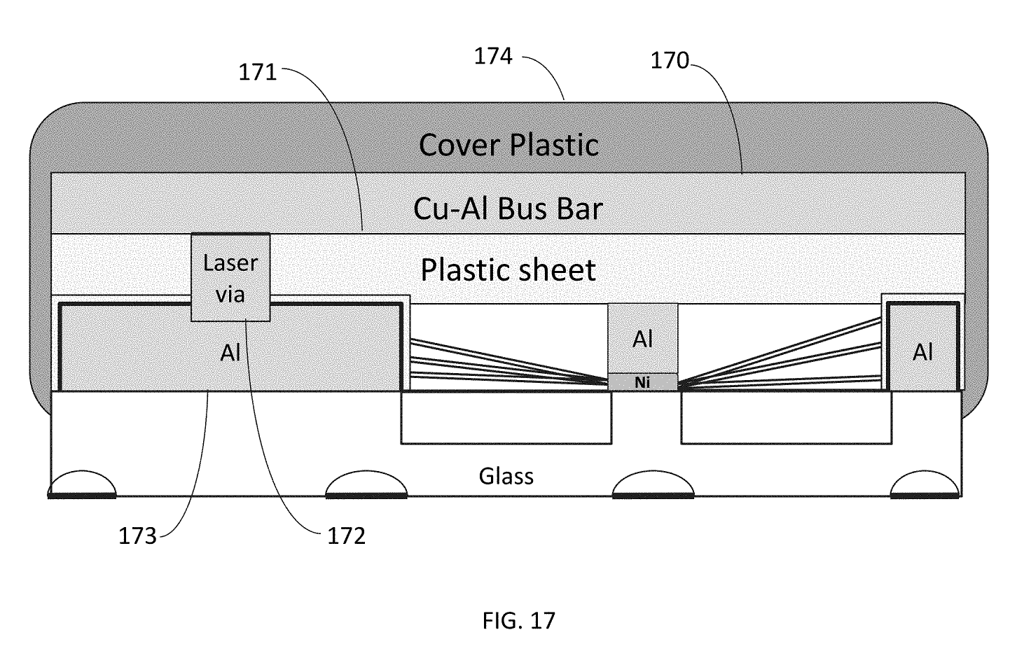

Semiconductor masking technology typically consists of steppers and contact printers. Typically steppers can print very fine geometries, such as the fingers above, but can only expose a small part of the die at a time. On the other hand, contact printers may expose the whole wafer at one time, but can only align and print very large objects. In order to construct a wafer-wide array of the structure shown in FIG. 6, it may be necessary to step a die pattern, which overlaps bus lines 61 and 62 at the top and bottom of the die pattern. Contact printing connecting the bus bar ends may then be done first, followed by the stepper printing of the dies. A wider gap 67 between the end of the power fingers 64 and the ground bus line 62 and between the end of the ground fingers 63 and the power bus line 61 may be sufficiently large enough to allow laser cutting one finger 68 or multiple fingers 69 shorted by defects 70 and 71, and as a method to self-align the resist 160 shown in FIG. 16, which may separate the Cu—Al bus bars 170 shown in FIG. 17.

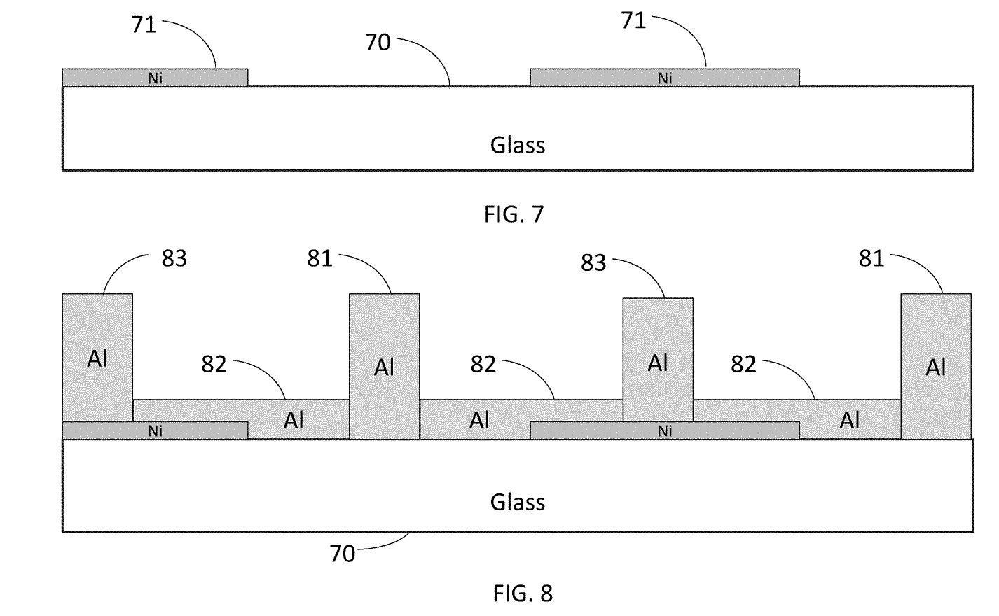

Reference is now made to FIGS. 7 through 15, cross-sections of an antenna array during successive steps in manufacture according to an embodiment of the invention. Initially a glass or quartz wafer may be used, and may later be replaced with rolls of glass. Normal liftoff masking may then be used to deposit a thin layer of nickel 71. Alternatively, an e-beam directed plasma-enhanced chemical vapor deposition (PECVD) process may deposit the nickel in ˜1 micron strips. Subsequently, a thicker layer of aluminum may be deposited on the glass, and stamped to form thicker power fingers 81, ground fingers 83 and thinner spaces 82 on the glass substrate 70. These processes may be done in different sections of one high-vacuum chamber. Subsequently, an etch may remove a sufficient amount of material to separate the ground fingers 93 and power fingers 91 and may create depressions in the glass 92 between them. Measuring the resistance between the power and ground lines may be used to control this etch process. Thereafter, a first oxide may be grown or deposited on the aluminum fingers 94 followed by a deposition of a second oxide 95, 101. The second oxide may be much thicker on the tops of the fingers 101 than the sides 95. Using a plasma etch and applying an electrical bias between the power and ground lines, a selective etch may be performed to remove the oxides from the ground fingers 100. Carbon nanotube antennas 110 may subsequently be grown from the nickel catalyst 111 to the double oxide diodes 112. While the power fingers 81 and ground fingers 83 may be stamped tall enough to minimize the number of carbon nanotubes that grow above the fingers, some carbon nanotubes 113 may grow over the top of the thicker oxide 114, which may not form antenna diode combinations because of the thick oxide. Subsequent to the carbon nanotube growth, a negative resist may be sprayed onto the bottom glass surface 120 and exposed 121 from above through the glass. After washing the unexposed resist away, the exposed resist 130 may remain, protecting the glass. Etching the bottom of the glass may create lenses 140 that may disperse the light towards the trenches 141. Thereafter, a plastic sheet 150 may be attached on top of the fingers, covering the whole glass, and resist 151 may be sprayed on the plastic sheet. The plastic sheet may be a polycarbonate sheet.

Reference is now made to FIG. 16, a top view of the vias and bus bars during steps of their construction, according to an embodiment of the invention. At the sides of the glass plate or roll, vertical bus lines may be formed by the edge of the aluminum stamp. The bus lines may have been adjusted at their ends to connect the ground bus lines 163 to the right vertical bus line 167 and the power bus lines 164 to the left vertical bus line 166.

It is well known that a polarizing grate may transmit light whose wavelength may be larger than the grate's spacing, if it is polarized perpendicular to the grate, and reflects light of the same wavelength, which may be parallel to the direction of the lines in the grate. By shining vertically polarized light up through the glass and plastic sheet, which may have a longer wavelength than the spacing between the fingers, resist over the gaps 162 and 163 and the ends of the rows of fingers between the vertical bus lines 166 and 167 and the bus lines 163, may be exposed. Washing away the unexposed resist may leave the resist 160, which may then be cured, forming a continuous serpentine separation between the power 164 and ground 163 bus lines. Laser scribing may then be used to form vias 165 through the plastic sheet. Optionally, an additional spray may be applied before laser scribing to enhance the scribing of the vias. Alternatively, non-polarized light may be used, which may be partially absorbed by the CNT antennas when the left and right vertical bus lines 166 and 167 may be electrically connected through a resistor which may remove the electrical energy, leaving the area not connected with CNT antennas to transmit the full power of the light, thereby exposing the resist 160.

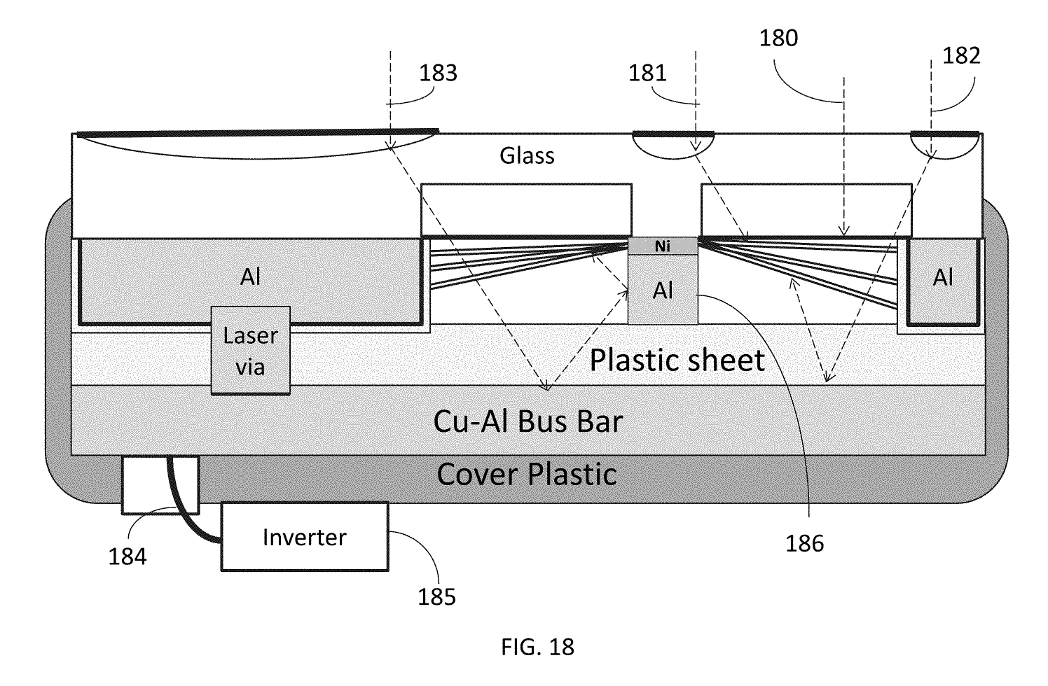

Reference is now made to FIGS. 17 and 18, cross-sections of an antenna array during the final steps of manufacturing according to an embodiment of the invention. Following scribing of the vias, a blade may be used to spread a film of copper-aluminum paste 170 across plastic sheet 171 separated into power and ground bus bars by the resist 160 shown in FIG. 16. The blade-spreading may also fill the vias 172, thereby connecting the bus bars 170 to the bus lines 173 underneath the plastic sheet 171. Finally, cover plastic 174 may be sprayed on and dried to seal the solar cell. The solar cell may be turned over for normal operation as shown in FIG. 18. The glass may be designed to block UV but transmit both visible and IR light 180 to maximize the absorption by the nanotube antennas. The etched indents may divert the light toward the nanotube antennas 181. The bus bars may be composed of a highly reflective material to reflect back to the nanotube antennas any light not initially absorbed 182, which may then be absorbed by the nanotube antennas. Furthermore, the aluminum fingers 186 may be tall enough to also reflect unabsorbed light back to the nanotube antennas. Wires 184 and inverters 185, to connect individual cells into larger panels, may be attached on the back of the solar cells.

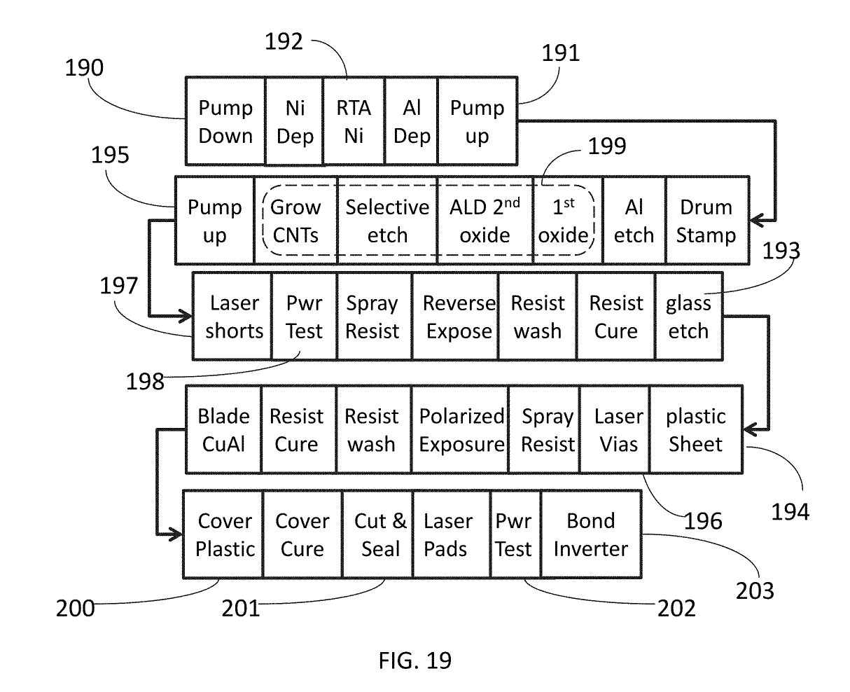

Reference is now made to FIG. 19, a diagram of continuous flow process steps according to an embodiment of the invention. The process may begin with a roll of thin glass and may end either with a roll of finished panels, or a stack of individually cut panels. To minimize cost, all the high-vacuum metal deposition steps, including the nickel anneal 192 may be done within a single vacuum chamber between pump down 190 and a partial pump up 191 to a low-torr pressure chamber, which may be used to perform metal etching and CNT growing steps followed by a pump up 195 to normal atmosphere because the subsequent glass etch 193 may be an isotropic wet etch. The plastic film may be attached 194 to the aluminum fingers using an adhesive, which may also enhance the laser etching of the vias 196. The laser shorts 197 cutting may be done by IR measurement while applying a voltage across adjacent power and ground lines. Results of the power test 198 may be used to adjust the oxide through CNT growth steps 199. For large runs of standard sized panels, the Cut & Seal 201 may occur before the Cover Plastic 200, saving an additional seal operation. The power test 202 may be used to grade the resulting solar cell sheets, and tune the inverter bonded to each solar cell sheet 203.

It will be appreciated by persons skilled in the art that the present invention is not limited by what has been particularly shown and described hereinabove. Rather the scope of the present invention includes both combinations and sub-combinations of various features described hereinabove as well as modifications and variations which would occur to persons skilled in the art upon reading the foregoing description and which are not in the prior art.

1. A solar antenna array configured to convert sunlight into electrical energy comprising:
a glass sheet;
a plurality of parallel ground fingers under the glass sheet;
a plurality of parallel voltage fingers under the glass sheet;
a clear insulating sheet under the ground fingers and the voltage fingers;
a power bus bar under the clear insulating sheet;
a ground bus bar under the clear insulating sheet;
a plurality of carbon nanotube antennas; and
a plurality of diodes;
wherein each of the ground fingers is electrically connected to the ground bus bar, and each of the voltage fingers is electrically connected to the power bus bar, and wherein each antenna is coupled to a ground finger and, through a diode, to a voltage finger, and
wherein the carbon nanotube antennas vary in length and in at least two dimensions of orientation for reception of multiple wavelengths of sunlight through the glass layer and reflected off the power bus bar and the ground bus bar.

2. (canceled)

3. The solar antenna array in claim 1, wherein one or more of the diodes are metal-oxide-carbon diodes.

4. The solar antenna array in claim 3, wherein one or more of the diodes is/are a combination of a carbon nanotube geometric diode and a metal-oxide-carbon diode.

5. The solar antenna array in claim 1, wherein one or more of the diodes are metal-insulator-insulator-carbon diodes.

6. The solar antenna array in claim 5, wherein one or more of the diodes is/are a combination of a carbon nanotube geometric diode and a metal-insulator-insulator-carbon diode.

7. The solar antenna array in claim 1, where the glass sheet includes one or more lenses above the fingers to disperse light above the fingers to the carbon nanotube antennas.

8. A method of fabricating a solar antenna array comprising:
power and ground bus bars;
a clear insulating sheet;
power and ground fingers; and
a glass sheet;
wherein the method comprises:
forming the power and ground fingers on top of the glass sheet;
forming the clear insulating sheet on top of the power and ground fingers; and
forming the ground and power bus bars on top of the clear insulating sheet after the clear insulating sheet is placed on top of the power and ground fingers after the power and ground fingers are placed on top of the glass sheet.

9. The method of fabricating a solar antenna array as in claim 8, further comprising operating the solar antenna array by inverting the structure formed according to claim 8.
